(19) United States
(12) Patent Application Publication
(10) Pub. No.: US 2022/0385034 A1
(43) Pub. Date: Dec. 1, 2022

(54) VERTICAL-CAVITY SURFACE-EMITTING LASER

(71) Applicant: Sumitomo Electric Industries, Ltd., Osaka-shi (JP)

(72) Inventor: Yuji KOYAMA, Osaka-shi (JP)

(73) Assignee: Sumitomo Electric Industries, Ltd., Osaka-shi (JP)

(21) Appl. No.: 17/729,124

(22) Filed: Apr. 26, 2022

(30) Foreign Application Priority Data
May 26, 2021 (JP) 2021-088273

(51) Int. Cl. H01S 5/042; H01S 5/183

(52) U.S. Cl. CPC H01S 5/04256; H01S 5/18327

(57) ABSTRACT

A vertical-cavity surface-emitting laser includes a post extending along a first axis and an electrode surrounding the first axis. The post includes a first distributed Bragg reflector, an active layer, and a second distributed Bragg reflector. The second distributed Bragg reflector includes a semiconductor region, a first high-resistance region, and a second high-resistance region. The first high-resistance region has an inner edge located farther from the first axis than the inner edge of the electrode in a direction orthogonal to the first axis. The second high-resistance region has an inner edge located closer to the first axis than the inner edge of the electrode in a direction orthogonal to the first axis. The first high-resistance region and the second high-resistance region have a first thickness and a second thickness, respectively. The second thickness is greater than the first thickness.

### CROSS REFERENCE TO RELATED APPLICATIONS

This application claims priority based on Japanese Patent Application No. 2021-088273, filed on May 26, 2021, and the entire contents of the Japanese patent application are incorporated herein by reference.

### TECHNICAL FIELD

The present disclosure relates to a vertical-cavity surface-emitting laser.

### BACKGROUND

Japanese Unexamined Patent Application Publication No. 2002-111051 discloses a vertical-cavity surface-emitting laser including a substrate, a lower distributed Bragg reflector provided on the substrate, an active layer provided on the lower distributed Bragg reflector, and an upper distributed Bragg reflector provided on the active layer. The vertical-cavity surface-emitting laser includes a light-emitting region including the active layer and a high-resistance region located around the light-emitting region. The high-resistance region extends from the upper surface of the upper distributed Bragg reflector to the active layer.

### SUMMARY

A vertical-cavity surface-emitting laser includes a post disposed on a main surface of a substrate, the post extending along a first axis intersecting the main surface of the substrate, and an electrode disposed on an upper surface of the post, the electrode surrounding the first axis. The post includes a first distributed Bragg reflector, an active layer, and a second distributed Bragg reflector. The substrate, the first distributed Bragg reflector, the active layer, and the second distributed Bragg reflector are arranged in sequence in a direction of the first axis. The second distributed Bragg reflector includes a semiconductor region, a first high-resistance region, and a second high-resistance region. The first high-resistance region and the second high-resistance region have higher electrical resistances than an electrical resistance of the semiconductor region. The first axis extends through the semiconductor region. The first high-resistance region and the second high-resistance region surround the semiconductor region. The second high-resistance region is located farther from the upper surface of the post than the first high-resistance region in the direction of the first axis. The first high-resistance region has an inner edge located farther from the first axis than an inner edge of the electrode in a direction orthogonal to the first axis. The second high-resistance region has an inner edge located closer to the first axis than the inner edge of the electrode in the direction orthogonal to the first axis. The first high-resistance region and the second high-resistance region have a first thickness and a second thickness in the direction of the first axis, respectively, the second thickness being larger than the first thickness.

### BRIEF DESCRIPTION OF THE DRAWINGS

The foregoing and other purposes, aspects and advantages will be better understood from the following detailed description with reference to the drawings.

FIG. 1 is a cross-sectional view schematically illustrating a vertical-cavity surface-emitting laser according to an embodiment.

FIG. 2 is an enlarged cross-sectional view of a portion of the vertical-cavity surface-emitting laser of FIG. 1.

FIG. 3 is a plan view of a portion of the vertical-cavity surface-emitting laser of FIG. 1.

FIG. 4 is a graph illustrating an example of a relationship between a depth from an upper surface of a post and a concentration of protons in a first region of the upper surface of the post.

FIG. 5 is a graph illustrating an example of a relationship between the depth from the upper surface of the post and a concentration of protons in a second region of the upper surface of the post.

FIG. 6 is a cross-sectional view illustrating one step of a method for manufacturing a vertical-cavity surface-emitting laser according to an embodiment.

FIG. 7 is a cross-sectional view illustrating one step of a method for manufacturing a vertical-cavity surface-emitting laser according to an embodiment.

### DETAILED DESCRIPTION

When the high-resistance region is expanded inward to reduce the light-emitting region, the capacitance of the upper distributed Bragg reflector decreases. As the capacitance decreases, the bandwidth of the vertical-cavity surface-emitting laser tends to increase. On the other hand, when the high-resistance region is expanded inward to reduce the light-emitting region, the electrical resistance of the upper distributed Bragg reflector increases. As the electrical resistance increases, the bandwidth of the vertical-cavity surface-emitting laser tends to be narrowed. Therefore, there is a trade-off relationship between capacitance and electrical resistance. Therefore, there is a limit to improving the bandwidth of the vertical-cavity surface-emitting laser.

The present disclosure provides a vertical-cavity surface-emitting laser operable in a wider bandwidth.

### DESCRIPTION OF EMBODIMENTS OF THE PRESENT DISCLOSURE

A vertical-cavity surface-emitting laser according to an embodiment includes a post disposed on a main surface of a substrate, the post extending along a first axis intersecting the main surface of the substrate, and an electrode disposed on an upper surface of the post, the electrode surrounding the first axis. The post includes a first distributed Bragg reflector, an active layer, and a second distributed Bragg reflector. The substrate, the first distributed Bragg reflector, the active layer, and the second distributed Bragg reflector are arranged in sequence in a direction of the first axis. The second distributed Bragg reflector includes a semiconductor region, a first high-resistance region, and a second high-resistance region. The first high-resistance region and the second high-resistance region have higher electrical resistances than an electrical resistance of the semiconductor region. The first axis extends through the semiconductor region. The first high-resistance region and the second high-resistance region surround the semiconductor region. The second high-resistance region is located farther from the upper surface of the post than the first high-resistance region in the direction of the first axis. The first high-resistance region has an inner edge located farther from the first axis than an inner edge of the electrode in a direction orthogonal to the first axis. The second high-resistance region has an inner edge located closer to the first axis than the inner edge of the electrode in the direction orthogonal to the first axis. The first high-resistance region and the second high-resistance region have a first thickness and a second thickness in the direction of the first axis, respectively, the second thickness being larger than the first thickness

According to the vertical-cavity surface-emitting laser, the capacitance of the second distributed Bragg reflector can be reduced by increasing the second thickness of the second high-resistance region and bringing the inner edge of the second high-resistance region closer to the first axis. On the other hand, by moving the inner edge of the first high-resistance region close to the electrode away from the first axis, the electrical resistance of the second distributed Bragg reflector can be reduced. Therefore, the vertical-cavity surface-emitting laser can operate in a wider bandwidth.

The inner edge of the first high-resistance region may be located farther from the first axis than an outer edge of the electrode in the direction orthogonal to the first axis. In this case, the electrical resistance of the second distributed Bragg reflector can be further reduced.

Each of the first high-resistance region and the second high-resistance region may include protons, and the first high-resistance region may have a higher peak concentration of the protons than a peak concentration of the protons in the second high-resistance region. In this case, the electrical resistance of the first high-resistance region can be made higher.

The post may further include a current confinement layer disposed between the active layer and the second distributed Bragg reflector. The current confinement layer may include an aperture portion and an oxide portion surrounding the aperture portion. The first axis may extend through the aperture portion. The inner edge of the second high-resistance region may be located farther from the first axis than an inner edge of the oxide portion in the direction orthogonal to the first axis. In this case, an increase in electrical resistance of the second distributed Bragg reflector can be suppressed.

### Details of Embodiments of the Present Disclosure

Hereinafter, embodiments of the present disclosure will be described in detail with reference to the accompanying drawings. In the description of the drawings, the same reference numerals are used for the same or equivalent elements, and redundant description is omitted. In the drawings, XYZ-coordinate axes are shown as necessary. An X-axis, a Y-axis, and a Z-axis intersect (for example, are orthogonal to) each other.

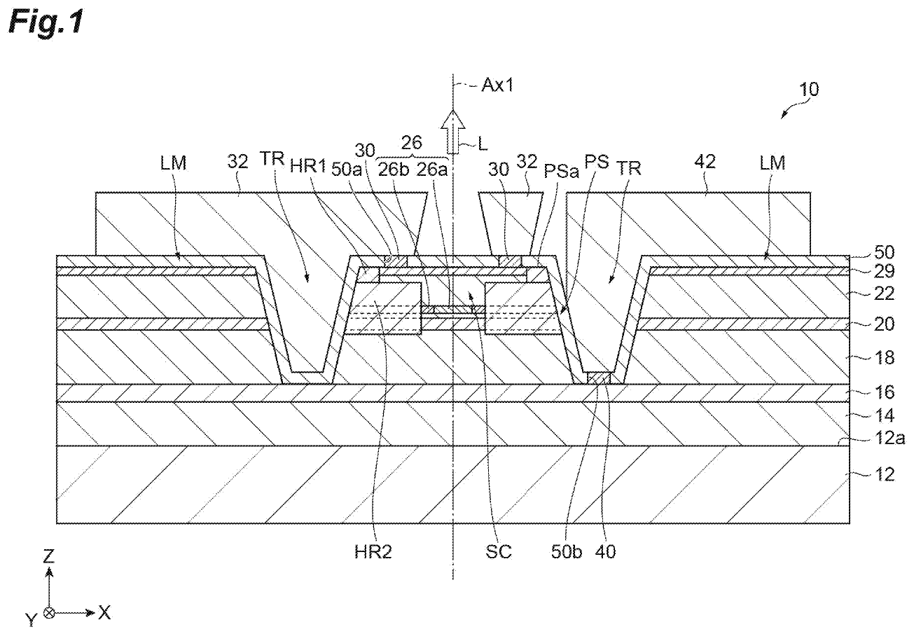

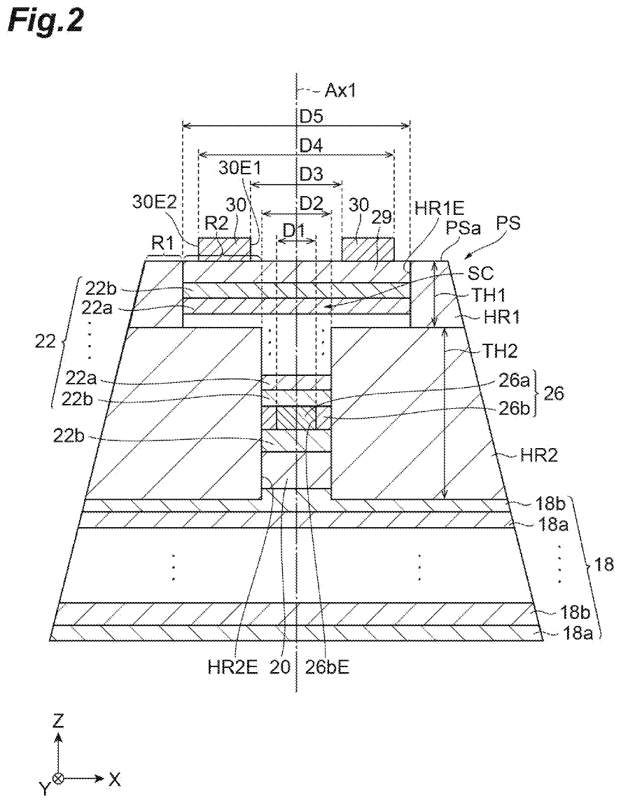

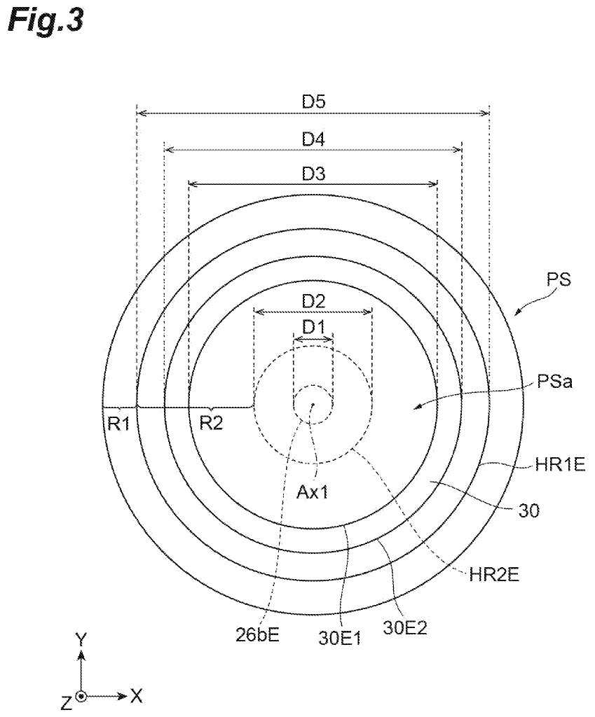

FIG. 1 is a cross-sectional view schematically illustrating a vertical-cavity surface-emitting laser according to an embodiment. FIG. 2 is an enlarged cross-sectional view of a portion of the vertical-cavity surface-emitting laser of FIG. 1. FIG. 3 is a plan view of a portion of the vertical-cavity surface-emitting laser of FIG. 1. A vertical-cavity surface-emitting laser (VCSEL) 10 illustrating in FIG. 1 includes a post PS provided on a main surface 12a of a substrate 12 and an electrode 30 provided on an upper surface PSa of post PS. Post PS extends along a first axis Ax1 that intersects main surface 12a of substrate 12. The direction in which first axis Ax1 extends coincides with the Z-axis. Electrode 30 surrounds first axis Ax1. Electrode 30 is, for example, a ring-shaped electrode.

Substrate 12 has main surface 12a including a group III-V compound semiconductor. Substrate 12 may be a III-V compound semiconductor substrate. Substrate 12 may be a substrate including a group III-V compound semiconductor layer and a base substrate. The group III-V compound semiconductor layer has main surface 12a. The base substrate supports a group III-V compound semiconductor layer. The group III-V compound semiconductor includes, for example, GaAs.

Post PS includes a first distributed Bragg reflector 18, an active layer 20, and a second distributed Bragg reflector 22. Substrate 12, first distributed Bragg reflector 18, active layer 20, and second distributed Bragg reflector 22 are arranged in sequence in the direction of first axis Ax1.

First distributed Bragg reflector 18 has a semiconductor multi-layer structure of a first conductivity type (for example, n-type). The semiconductor multi-layer structure includes a semiconductor layer 18a and a semiconductor layer 18b alternately arranged in a direction of first axis Ax1. Semiconductor layer 18a and semiconductor layer 18b have different refractive indices. Semiconductor layer 18a has, for example, a lower refractive index than that of semiconductor layer 18b. Each of semiconductor layer 18a and semiconductor layer 18b includes a group III-V compound semiconductor such as AlGaAs. An example of an n-type dopant is silicon.

Active layer 20 has, for example, a multiple quantum well structure. The multiple quantum well structure may include GaAs layers (or AlGaAs layers) and AlGaAs layers alternately arranged along first axis Ax1.

Second distributed Bragg reflector 22 has a semiconductor multi-layer structure of a second conductivity type (for example, p-type). The second conductivity type is opposite to the first conductivity type. The semiconductor multi-layer structure includes a semiconductor layer 22a and a semiconductor layer 22b alternately arranged in a direction of first axis Ax1. Semiconductor layer 22a and semiconductor layer 22b have different refractive indices. Semiconductor layer 22a has, for example, a lower refractive index than that of semiconductor layer 22b. Each of semiconductor layer 22a and semiconductor layer 22b includes a group III-V compound semiconductor such as AlGaAs.

A contact layer 29 of the second conductivity type (for example, p-type) may be provided on second distributed Bragg reflector 22. Contact layer 29 has upper surface PSa of post PS. Contact layer 29 includes a group III-V compound semiconductor such as AlGaAs.

Post PS may include a current confinement layer 26 disposed between active layer 20 and second distributed Bragg reflector 22. Current confinement layer 26 includes an aperture portion 26a and an oxide portion 26b surrounding aperture portion 26a. First axis Ax1 passes through aperture portion 26a. Aperture portion 26a is a semiconductor layer of the second conductivity type (for example, p-type). Aperture portion 26a includes a group III-V compound semiconductor containing aluminum as a group III element. Aperture portion 26a includes a group III-V compound semiconductor such as AlGaAs. Oxide portion 26b includes an aluminum oxide. Aperture portion 26a has an electrical resistance that is lower than an electrical resistance of oxide portion 26b. Semiconductor layer 22b may be provided between current confinement layer 26 and active layer 20.

A third distributed Bragg reflector 14 may be provided between substrate 12 and post PS. Third distributed Bragg reflector 14 has, for example, a semiconductor multi-layer structure of the first conductivity type (for example, n-type). The semiconductor multi-layer structure may have an i-type. The semiconductor multi-layer structure includes a plurality of semiconductor layers alternately arranged in the direction of first axis Ax1. The plurality of semiconductor layers have different refractive indices. Each semiconductor layer includes a group III-V compound semiconductor such as AlGaAs.

A contact layer 16 of the first conductivity type (for example, n-type) may be provided between third distributed Bragg reflector 14 and post PS. Contact layer 16 includes a group III-V compound semiconductor such as AlGaAs.

A vertical-cavity surface-emitting laser 10 may include a semiconductor multi-layer structure LM provided on main surface 12a of substrate 12. Third distributed Bragg reflector 14 and contact layer 16 are provided between substrate 12 and semiconductor multi-layer structure LM. Semiconductor multi-layer structure LM has the same layer structure as post PS. Semiconductor multi-layer structure LM and post PS are arranged in a direction (for example, the X-axis) orthogonal to first axis Ax1. A trench TR surrounding post PS may be formed between semiconductor multi-layer structure LM and post PS. A bottom of trench TR reaches contact layer 16.

An insulating layer 50 may be provided on semiconductor multi-layer structure LM, trench TR, and post PS. On upper surface PSa of post PS, insulating layer 50 has a first opening 50a. Electrode 30 is provided in first opening 50a. At the bottom of trench TR, insulating layer 50 has a second opening 50b. An electrode 40 is provided in second opening 50b.

Electrode 30 is in ohmic contact with upper surface PSa of post PS. A wiring 32 may be electrically connected to electrode 30. Wiring 32 extends from upper surface PSa of post PS beyond trench TR to semiconductor multi-layer structure LM.

Electrode 40 is in ohmic contact with contact layer 16. A wiring 42 may be electrically connected to electrode 40. Wiring 42 extends from trench TR to semiconductor multi-layer structure LM.

Second distributed Bragg reflector 22 includes a semiconductor region SC, a first high-resistance region HR1, and a second high-resistance region HR2. Semiconductor region SC includes semiconductor layer 22a and semiconductor layer 22b. First high-resistance region HR1 and second high-resistance region HR2 have electrical resistances higher than an electrical resistance of semiconductor region SC. Each of first high-resistance region HR1 and second high-resistance region HR2 may include protons. First axis Ax1 passes through a center of semiconductor region SC. The center of semiconductor region SC may be a center of gravity of a cross-sectional shape of semiconductor region SC orthogonal to first axis Ax1. First high-resistance region HR1 and second high-resistance region HR2 surround semiconductor region SC and first axis Ax1. First high-resistance region HR1 and second high-resistance region HR2 are, for example, ring-shaped regions.

Second high-resistance region HR2 is located farther than first high-resistance region HR1 from upper surface PSa of post PS in the direction of the first axis Ax1. To be specific, second high-resistance region HR2 is formed at a position deeper than first high-resistance region HR1 from upper surface PSa. First high-resistance region HR1 may be disposed between upper surface PSa and second high-resistance region HR2 in the direction of first axis Ax1. An upper portion of second high-resistance region HR2 may be in contact with a lower portion of first high-resistance region HR1.

First high-resistance region HR1 may be formed in contact layer 29. Second high-resistance region HR2 may be formed in a part of current confinement layer 26, a part of semiconductor layer 22b, a part of active layer 20, and a part of first distributed Bragg reflector 18.

As shown in FIGS. 2 and 3, first high-resistance region HR1 has an inner edge HR1E located outside an inner edge 30E1 of electrode 30 when viewed from the direction of the first axis Ax1. That is, first high-resistance region HR1 has inner edge HR1E located closer to first axis Ax1 than inner edge 30E1 of electrode 30 in a direction (for example, the X-axis) orthogonal to the first axis Ax1. Inner edge HR1E is disposed between inner edge 30E1 and the first axis Ax1 in a direction (for example, the X-axis) orthogonal to first axis Ax1. Inner edge HR1E of first high-resistance region HR1 is located outside an outer edge 30E2 of electrode 30 in FIGS. 2 and 3 when viewed from the direction of the first axis Ax1, but may be located inside an outer edge 30E2 of electrode 30. That is, inner edge HR1E of first high-resistance region HR1 is located farther from first axis Ax1 than outer edge 30E2 of electrode 30 in the direction orthogonal to first axis Ax1 (for example, the X-axis), but may be located closer to first axis Ax1 than the outer edge 30E2 of electrode 30. The outer edge of first high-resistance region HR1 may constitute a side surface of post PS. An inner diameter D3 of electrode 30 may be from 12 μm to 22 μm. An outer diameter D4 of electrode 30 may be from 16 μm to 26 μm. An inner diameter D5 of the first high-resistance region HR1 may be from 20 μm to 30 μm.

Second high-resistance region HR2 has an inner edge HR2E located inside inner edge 30E1 of electrode 30 when viewed from the direction of first axis Ax1. That is, second high-resistance region HR has inner edge HR2E located closer to first axis Ax1 than inner edge 30E1 of electrode 30 in the direction orthogonal to first axis Ax1 (e.g., the X-axis). Inner edge HR2E of second high-resistance region HR2 may be located outside inner edge 26bE of oxide portion 26b when viewed from the direction of the first axis Ax1. That is, inner edge HR2E of second high-resistance region HR2 may be located farther from first axis Ax1 than inner edge 26bE of oxide portion 26b in a direction (e.g., the X-axis) orthogonal to first axis Ax1. The outer edge of second high-resistance region HR2 may constitute a side surface of post PS. An inner diameter D1 (outer diameter of aperture portion 26a) of the oxide portion 26b may be from 7 μm to 9 μm. An inner diameter D2 of the second high-resistance region HR2 may be from 10 μm to 15 μm.

First high-resistance region HR1 and second high-resistance region HR2 have a first thickness TH1 and a second thickness TH2, respectively, along the direction of the first axis Ax1. Second thickness TH2 is greater than first thickness TH1. First thickness TH1 is from 1 μm to 2 μm, for example. Second thickness TH2 is, for example, from 3 μm to 5 μm.

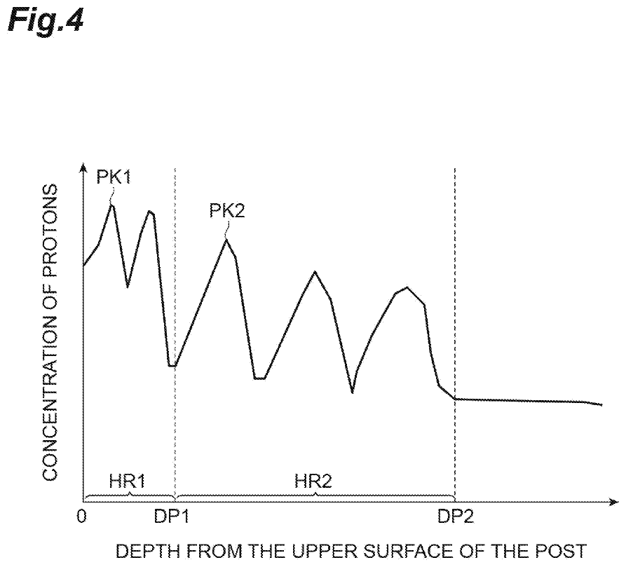

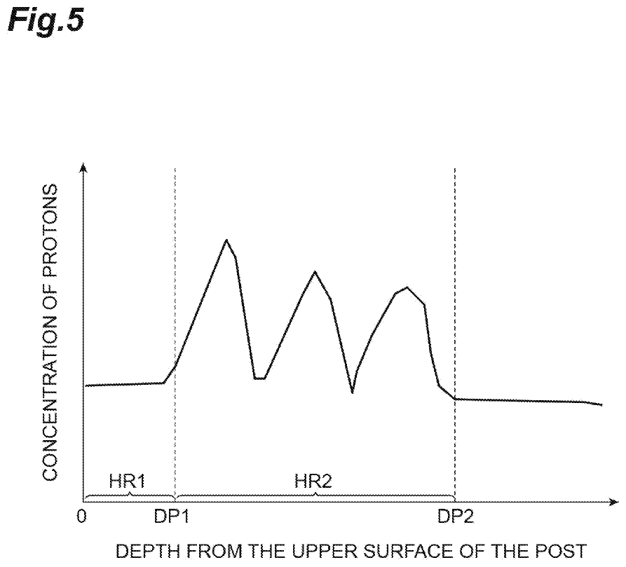

FIG. 4 is a graph illustrating an example of a relationship between a depth from the upper surface of the post and a concentration of protons in the first region of the upper surface of the post. FIG. 5 is a graph illustrating an example of a relationship between the depth from the upper surface of the post and a concentration of protons in the second region of the upper surface of the post. In each graph, the vertical axis represents the concentration of protons. The horizontal axis of the graph of FIG. 4 represents the depth from upper surface PSa of post PS in a first region R1 of upper surface PSa of post PS. As shown in FIG. 3, first region R1 is a region from the outer edge of upper surface PSa of post PS to inner edge HR1E of first high-resistance region HR1 when viewed from the direction of the first axis Ax1. The horizontal axis of the graph of FIG. 5 represents the depth from upper surface PSa of post PS in a second region R2 of upper surface PSa of post PS. As shown in FIG. 3, second region R2 is a region from inner edge HR1E of first high-resistance region HR1 to inner edge HR2E of second high-resistance region HR2 when viewed from the direction of the first axis Ax1. The concentration of protons can be measured by scanning a cross section of post PS including first axis Ax1 using a scanning capacitance microscope (SCM). As shown in FIGS. 4 and 5, the concentration of protons continuously changes according to the depth from upper surface PSa. A change in the concentration of protons shows a plurality of peaks at which the concentration of protons is locally maximized at a certain depth.

As shown in the graph of FIG. 4, in first region R1, first high-resistance region HR1 is formed from upper surface PSa of post PS to a first depth DP1. In first region R1, second high-resistance region HR2 is formed from first depth DP1 to a second depth DP2. First depth DP1 coincides with the first thickness TH1. The second depth DP2 is equal to a sum of first thickness TH1 and second thickness TH2. A peak PK1 of concentration of protons in first high-resistance region HR1 may be greater than a peak PK2 of concentration of protons in second high-resistance region HR2. Peak PK1 and peak PK2 of concentration of the protons are, for example, 1×10¹⁸ cm⁻³ or more or 1×10¹⁹ cm⁻³ or more. In each of first high-resistance region HR1 and second high-resistance region HR2, the concentration profile of protons may have a plurality of peaks. The concentration profile of protons can be adjusted by the energy and dose at the time of ion implantation.

As shown in the graph of FIG. 5, in second region R2, first high-resistance region HR1 is not formed from upper surface PSa of post PS to first depth DP1. In second region R2, second high-resistance region R2 is formed from first depth DP1 to second depth DP2.

In vertical-cavity surface-emitting laser 10, when a voltage is applied between electrode 30 and electrode 40, a bias current is supplied to active layer 20 through current confinement layer 26. Thus, a laser light L is emitted in the direction of first axis Ax1.

According to vertical-cavity surface-emitting laser 10, a capacitance of second distributed Bragg reflector 22 can be reduced by increasing second thickness TH2 of second high-resistance region HR2 and bringing inner edge HR2E of second high-resistance region HR2 closer to first axis Ax1. On the other hand, by moving inner edge HR1E of first high-resistance region HR1 closer to electrode 30 in the direction of first axis Ax1 away from first axis Ax1, an electrical resistance to the bias current passing through second distributed Bragg reflector 22 can be reduced. Therefore, vertical-cavity surface-emitting laser 10 can operate in a wider bandwidth. According to vertical-cavity surface-emitting laser 10, the 3-dB bandwidth can be increased.

When inner edge HR1E of first high-resistance region HR1 is located outside outer edge 30E2 of electrode 30, an area where electrode 30 is in contact with the upper surface of semiconductor region SC increases. As a result, a contact resistance can be reduced, and the electrical resistance of second distributed Bragg reflector 22 can be further reduced.

When peak PK1 of concentration of the protons in first high-resistance region HR1 is greater than peak PK2 of concentration of the protons in second high-resistance region HR2, the electrical resistance of first high-resistance region HR1 can be increased.

When inner edge HR2E of second high-resistance region HR2 is located outside inner edge 26bE of oxide portion 26b, an increase in the electrical resistance of second distributed Bragg reflector 22 can be suppressed.

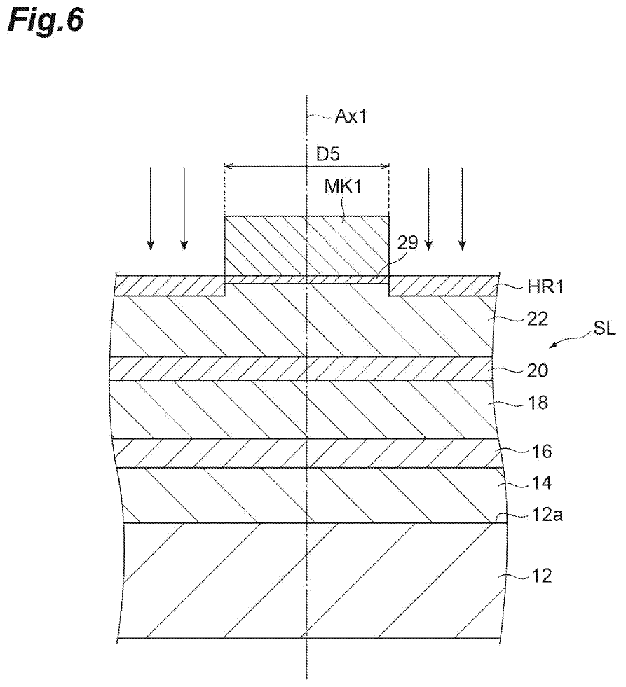

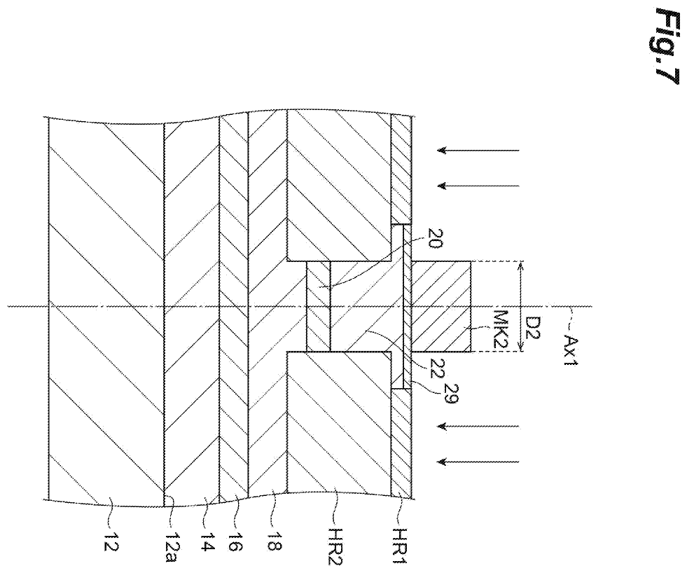

FIGS. 6 and 7 are cross-sectional views illustrating one step of a method for manufacturing a vertical-cavity surface-emitting laser according to an embodiment. Vertical-cavity surface-emitting laser 10 may be manufactured as follows.

First, as shown in FIG. 6, a semiconductor stack SL may be formed on main surface 12a of substrate 12. Semiconductor stack SL includes third distributed Bragg reflector 14, contact layer 16, first distributed Bragg reflector 18, active layer 20, second distributed Bragg reflector 22, and contact layer 29. Third distributed Bragg reflector 14, contact layer 16, first distributed Bragg reflector 18, active layer 20, second distributed Bragg reflector 22, and contact layer 29 are formed in sequence on substrate 12. Each layer is formed by, for example, an organometallic vapor phase epitaxy (OMVPE) method.

Next, a mask MK1 is formed on semiconductor stack SL. Mask MK1 is, for example, a resist mask. First axis Ax1 passes through mask MK1. Mask MK1 is, for example, circular when viewed from first axis Ax1. In a direction orthogonal to first axis Ax1, mask MK1 has the same radius as inner diameter D5 of first high-resistance region HR1. Thereafter, ions are implanted into semiconductor stack SL. Thus, first high-resistance region HR1 is formed. The ions to be implanted are, for example, protons. Thereafter, mask MK1 is removed.

Next, as shown in FIG. 7, a mask MK2 is formed on semiconductor stack SL. Mask MK2 is, for example, a resist mask. First axis Ax1 passes through mask MK2. Mask MK2 is, for example, circular when viewed from first axis Ax1. In a direction orthogonal to first axis Ax1, mask MK2 has a radius smaller than that of mask MK1. Mask MK2 has the same radius as inner diameter D2 of second high-resistance region HR2. Thereafter, ions are implanted into semiconductor stack SL. Thus, second high-resistance region HR2 is formed. The ions to be implanted are, for example, protons. The energy of the ion implantation when forming second high-resistance region HR2 is greater than the energy of the ion implantation when forming first high-resistance region HR1. As a result, second high-resistance region HR2 is formed at a position deeper than first high-resistance region HR1 in the direction of first axis Ax1.

Next, trench TR shown in FIG. 1 is formed by, for example, photolithography and etching. Thus, post PS and semiconductor multi-layer structure LM are formed. Thereafter, oxide portion 26b of current confinement layer 26 is formed by oxidizing the side surface of post PS. Thereafter, insulating layer 50 is formed. Thereafter, electrode 30 and electrode 40 are formed. Thereafter, wiring 32 and wiring 42 are formed.

Although the preferred embodiments of the present disclosure have been described in detail above, the present disclosure is not limited to the above embodiments. The constituent elements of the embodiments may be arbitrarily combined.

For example, although second high-resistance region HR2 is formed after first high-resistance region HR1 is formed in the embodiment described above, first high-resistance region HR1 may be formed after second high-resistance region HR2 is formed. In this case, after ion implantation is performed using mask MK2, ion implantation is performed using mask MK1.

It should be understood that the embodiments disclosed herein are illustrative and non-restrictive in every respect. The scope of the present invention is defined by the claims rather than the meaning described above, and is intended to include all modifications within the meaning and scope equivalent to the claims.

What is claimed is:

1. A vertical-cavity surface-emitting laser comprising:
a post disposed on a main surface of a substrate, the post extending along a first axis intersecting the main surface of the substrate; and
an electrode disposed on an upper surface of the post, the electrode surrounding the first axis, wherein
the post includes a first distributed Bragg reflector, an active layer, and a second distributed Bragg reflector,
the substrate, the first distributed Bragg reflector, the active layer, and the second distributed Bragg reflector are arranged in sequence in a direction of the first axis,
the second distributed Bragg reflector includes a semiconductor region, a first high-resistance region, and a second high-resistance region,
the first high-resistance region and the second high-resistance region have higher electrical resistances than an electrical resistance of the semiconductor region,
the first axis extends through the semiconductor region,
the first high-resistance region and the second high-resistance region surround the semiconductor region,
the second high-resistance region is located farther from the upper surface of the post than the first high-resistance region in the direction of the first axis,
the first high-resistance region has an inner edge located farther from the first axis than an inner edge of the electrode in a direction orthogonal to the first axis,
the second high-resistance region has an inner edge located closer to the first axis than the inner edge of the electrode in the direction orthogonal to the first axis, and
the first high-resistance region and the second high-resistance region have a first thickness and a second thickness in the direction of the first axis, respectively, the second thickness being larger than the first thickness.

2. The vertical-cavity surface-emitting laser according to claim 1, wherein the inner edge of the first high-resistance region is located farther from the first axis than an outer edge of the electrode in the direction orthogonal to the first axis.

3. The vertical-cavity surface-emitting laser according to claim 1, wherein each of the first high-resistance region and the second high-resistance region includes protons, and
the first high-resistance region has a higher peak concentration of the protons than a peak concentration of the protons in the second high-resistance region.

4. The vertical-cavity surface-emitting laser according to claim 3, wherein the peak concentration of the protons in the first high-resistance region and the peak concentration of the protons in the second high-resistance region are 1×10¹⁸ cm⁻³ or more.

5. The vertical-cavity surface-emitting laser according to claim 3, wherein the peak concentration of the protons in the first high-resistance region and the peak concentration of the protons in the second high-resistance region are 1×10¹⁹ cm⁻³ or more.

6. The vertical-cavity surface-emitting laser according to claim 1, wherein each of the first high-resistance region and the second high-resistance region includes protons, and
a concentration of the protons in the first high-resistance region and a concentration of the protons in the second high-resistance region continuously change according to a depth from the upper surface of the post.

7. The vertical-cavity surface-emitting laser according to claim 1, wherein each of the first high-resistance region and the second high-resistance region includes protons, and
each of the first high-resistance region and the second high-resistance region has a plurality of peak concentrations of the protons.

8. The vertical-cavity surface-emitting laser according to claim 1, wherein
the post further includes a current confinement layer disposed between the active layer and the second distributed Bragg reflector,
the current confinement layer includes an aperture portion and an oxide portion surrounding the aperture portion,
the first axis extends through the aperture portion, and
the inner edge of the second high-resistance region is located farther from the first axis than an inner edge of the oxide portion in the direction orthogonal to the first axis.

9. The vertical-cavity surface-emitting laser according to claim 8, wherein an inner diameter of the oxide portion is from 7 μm to 9 μm.

10. The vertical-cavity surface-emitting laser according to claim 1, wherein an inner diameter of the electrode is from 12 μm to 22 μm.

11. The vertical-cavity surface-emitting laser according to claim 1, wherein an outer diameter of the electrode is from 16 μm to 26 μm.

12. The vertical-cavity surface-emitting laser according to claim 1, wherein an inner diameter of the first high-resistance region is from 20 μm to 30 μm.

13. The vertical-cavity surface-emitting laser according to claim 1, wherein an inner diameter of the second high-resistance region is from 10 μm to 15 μm.

14. The vertical-cavity surface-emitting laser according to claim 1, wherein the first thickness is from 1 μm to 2 μm.

15. The vertical-cavity surface-emitting laser according to claim 1, wherein the second thickness is from 3 μm to 5 μm.

16. The vertical-cavity surface-emitting laser according to claim 1, wherein
the first high-resistance region is formed from the upper surface of the post to a first depth,
the second high-resistance region is formed from the first depth to a second depth,
the first depth coincides with the first thickness, and
the second depth coincides with a sum of the first thickness and the second thickness.
